(19) United States
(12) Patent Application Publication
(10) Pub. No.: US 2012/0182433 A1
(43) Pub. Date: Jul. 19, 2012

(54) OPTICALLY TRANSMISSIVE SUBSTRATE HAVING A FIDUCIAL MARK AND METHODS OF ALIGNING OPTICALLY TRANSMISSIVE SUBSTRATES

(76) Inventors: Mark R. Dupre, Oakdale, MN (US); Steven M. Spicer, Cottage Grove, MN (US); James P. Burke, St. Paul, MN (US); Andrew K. Hartzell, Hudson, WI (US); Catharine B. Shay, Maplewood, MN (US)

(21) Appl. No.: 13/498,828

(22) PCT Filed: Sep. 24, 2010
(86) PCT No.: PCT/US10/50174

§ 371 Date: Mar. 28, 2012

Related U.S. Application Data
(60) Provisional application No. 61/246,668, filed on Sep. 29, 2009.

(51) Int. Cl. H04N 5/225; G02B 5/08; H01L 31/04; G02B 17/00

(52) U.S. Cl. 348/207.1; 359/726; 359/838; 136/259; 348/E05.024

(57) ABSTRACT

An article comprises an optically transmissive substrate comprising a plurality of functional elements and an integral fiducial mark. The substrate has a critical angle for total internal reflection, and a length and a width defining a reference plane. The substrate comprises an integral fiducial mark disposed on the major surface. The integral fiducial mark comprises at least one substantially ellipse-like feature formed by first and second frustoconical surfaces that together with a reference line that is normal to the reference plane define respective first and second half angles. The first and second half angles are less than or equal to 90 degrees minus the critical angle for total internal reflection expressed in degrees. A method comprises: providing an optically transmissive substrate according to the present disclosure; precisely detecting a position of the fiducial mark with aid of a machine vision system; and optionally precisely aligning the substrate.

### TECHNICAL FIELD

The present disclosure broadly relates to optically transmissive substrates having a fiducial mark and methods of aligning the same.

### BACKGROUND

Registration marks used to assist in precision alignment during manufacturing are commonly known as fiducial marks. Fiducial marks are often used for precision measuring, installation, and assembly of parts incorporating vision systems. For example, robots equipped with machine vision systems use fiducial marks to precisely place parts automatically. In such applications, the machine vision system captures an image of a fiducial mark and uses it to identify a reference point for alignment. As few as one fiducial mark may be used, or additional fiducial marks may be used depending on the desired level of precision.

In typical machine vision systems, computer software attempts to “recognize” a fiducial mark (e.g., a circular fiducial mark) based on an image of the fiducial mark obtained using a camera. This fiducial mark may be filled in to resemble a dot or an annulus. The fiducial mark image is typically printed on a substrate using an opaque ink, although scribing and punching are also known alternative methods for creating fiducial marks.

Generally, machine vision systems look for contrast between the fiducial mark and the surrounding area. For many substrates, this presents little if any problem. However, in the case of optically transmissive substrates, obtaining a reliable sufficient degree of contrast can be a major problem. For example, with transparent acrylic sheeting, it can be challenging to control the light from the vision system as well as other light sources so that a suitable contrasting image can be produced. In such cases, reflection, refraction, transmission, absorption, and scattering of these materials must be considered.

In some cases, a printed, punched, or scribed fiducial mark is acceptable on optically transmissive materials provided they are large or deep enough to provide required contrast. More commonly, however, it is unacceptable to use fiducial marks that are too large or too noticeable due to performance and/or aesthetic reasons.

### SUMMARY

In one aspect, the present disclosure provides an article comprising a substrate having a major surface, wherein the substrate is optically transmissive and has a critical angle for total internal reflection (θ_{c,}), wherein the substrate has a length and a width defining a reference plane, wherein the substrate comprises an integral fiducial mark disposed on the major surface, wherein the fiducial mark comprises at least one substantially ellipse-like feature formed by first and second frustoconical surfaces that together with a reference line that is normal to the reference plane define respective first and second half angles, and wherein the first and second half angles are less than or equal to 90 degrees minus the critical angle for total internal reflection expressed in degrees.

In another aspect, the present disclosure provides a method comprising:

providing a substrate having a first major surface, wherein the substrate is optically transmissive and has a critical angle for total internal reflection, wherein the substrate has a length and a width defining a reference plane, wherein the substrate comprises an integral fiducial mark disposed on the first major surface, wherein the fiducial mark comprises at least one substantially ellipse-like feature formed by first and second frustoconical surfaces that together with a reference line that is normal to the reference plane define respective first and second half angles, and wherein the first and second half angles are less than or equal to 90 degrees minus the critical angle for total internal reflection expressed in degrees; and

precisely detecting a position of the integral fiducial mark using a machine vision system, wherein the machine vision system comprises a camera aligned to receive light normal to the reference plane, and wherein the camera is in communication with a computer having image analysis software implemented thereon.

In some embodiments, the method further comprises precisely aligning the substrate. In some embodiments, the machine vision system further comprises a light source that emits light substantially coaxially aligned with the camera. In some embodiments, the at least one substantially ellipse-like feature comprises a ridge extending outwardly from the first major surface. In some embodiments, the at least one substantially ellipse-like feature comprises a groove extending inwardly from the first major surface. In some embodiments, the substrate further comprises a second major surface opposite the first major surface, and the camera is disposed facing the second major surface. In some embodiments, the light source and the camera are disposed facing the same side of the substrate.

In some embodiments, the integral fiducial mark is centrally disposed with respect to the major surface (or the first major surface). In some embodiments, the substrate further comprises a plurality of functional elements. In some embodiments, the at least one substantially ellipse-like feature comprises a ridge extending outwardly from the major surface (or the first major surface). In some embodiments, the at least one substantially ellipse-like feature comprises a groove extending inwardly from the major surface (or the first major surface). In some embodiments, the plurality of functional elements comprises at least one of optical or electronic elements. In some embodiments, the plurality of functional elements comprises a Fresnel lens. In some of these embodiments, the article further comprises a photovoltaic cell, wherein the Fresnel lens is optically aligned with respect to the photovoltaic cell.

In some embodiments, the integral fiducial mark has an area of less than or equal to 2 square millimeters. In some embodiments, the at least one substantially ellipse-like feature is circular. In some embodiments, the integral fiducial mark is formed on at least one of the plurality of functional elements. In some embodiments, the substrate comprises an organic polymer.

All of the various foregoing embodiments may be combined in any combination not evidently contrary to the present disclosure.

Advantageously, the present disclosure provides articles and methods for aligning transparent or translucent articles using machine vision systems by enhancing the contrast of a fiducial mark relative to its background while minimizing the size of the fiducial mark. Additionally, the fiducial mark may be machined during the initial tool cutting process for production of various articles (e.g., a Fresnel lens), and can therefore be reliably and accurately placed in relation to the center of the article.

As used herein:

The term “cone” refers to a geometric shape having an ellipse-like base and a surface that tapers upwardly and inwardly to a point (i.e., the tip).

The phrase “critical angle for total internal reflection” of a material refers to the critical angle in degrees for total internal reflection of the material at an air interface.

The term “ellipse-like” means shaped as an ellipse or circle.

The term “frustoconical” used in referring to the shape of an object means that the object is substantially shaped as a tapered surface of a frustum.

The term “frustum” refers to a part of a right cone that remains after cutting off a top portion with a plane that is substantially parallel to the base of the solid.

The term “optically transmissive” means at least partially transmissive of electromagnetic radiation in a wavelength range of from 400 to 700 nanometers. As applied to a material, it includes transparent and/or translucent materials that may optionally be colored (e.g., an optical filter).

The term “precisely” means to within a tolerance of 100 micrometers.

The term “right cone” refers to a cone wherein a right angle is formed by the base and an axis defined by the tip of the cone and the geometric center of the base; the base may be elliptical or circular.

### BRIEF DESCRIPTION OF THE DRAWINGS

FIG. 1 is a schematic perspective view of an exemplary article according to the present disclosure;

FIGS. 2A-2B are cutaway schematic side views of exemplary fiducial markings;

FIG. 3 is a schematic cutaway side view of an exemplary fiducial marking;

FIG. 4 is a schematic cutaway side view of an exemplary fiducial marking disposed on a functional element;

FIG. 5 is a schematic view of an exemplary machine vision detection/manipulation system;

FIG. 6 is a schematic side view of an exemplary article according to the present disclosure;

FIG. 7 is a digital photograph of the Fresnel lens described in Comparative Example A having a cross-hatch fiducial marking;

FIG. 8 is a digital photograph of the Fresnel lens described in Example 1 having a circular fiducial marking wherein the fiducial marking faces away from the camera; and

FIG. 9 is a digital photograph of the Fresnel lens described in Example 1 having a circular fiducial marking wherein the fiducial marking faces toward the camera.

### DETAILED DESCRIPTION

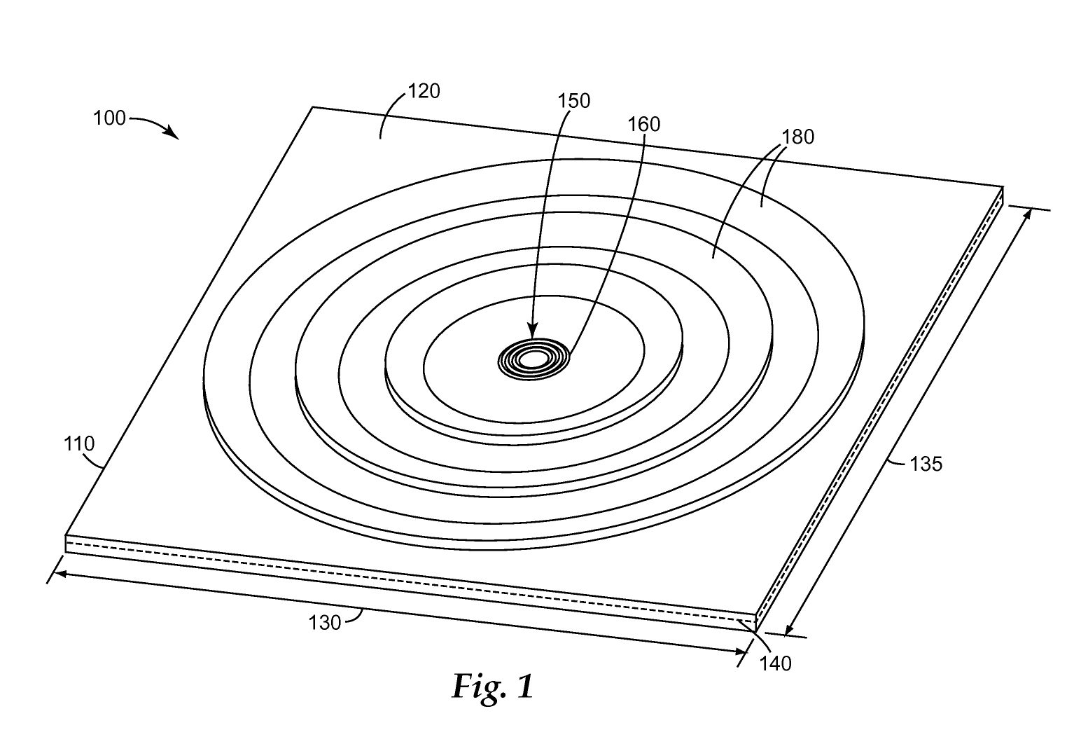

In one exemplary embodiment of the present disclosure, the article comprises a Fresnel lens. Referring now to FIG. 1, article 100 comprises substrate 110 which has major surface 120. Substrate 110 is optically transmissive and has a critical angle for total internal reflection (θ_{c}, not shown). Substrate 100 has length 130 and width 135 that together define reference plane 140. Substrate 100 has integral fiducial mark 150, which comprises at least one substantially ellipse-like feature 160, disposed on major surface 120. Optional functional elements 180 are arranged to form a Fresnel lens. Fiducial mark 150 may have various configurations.

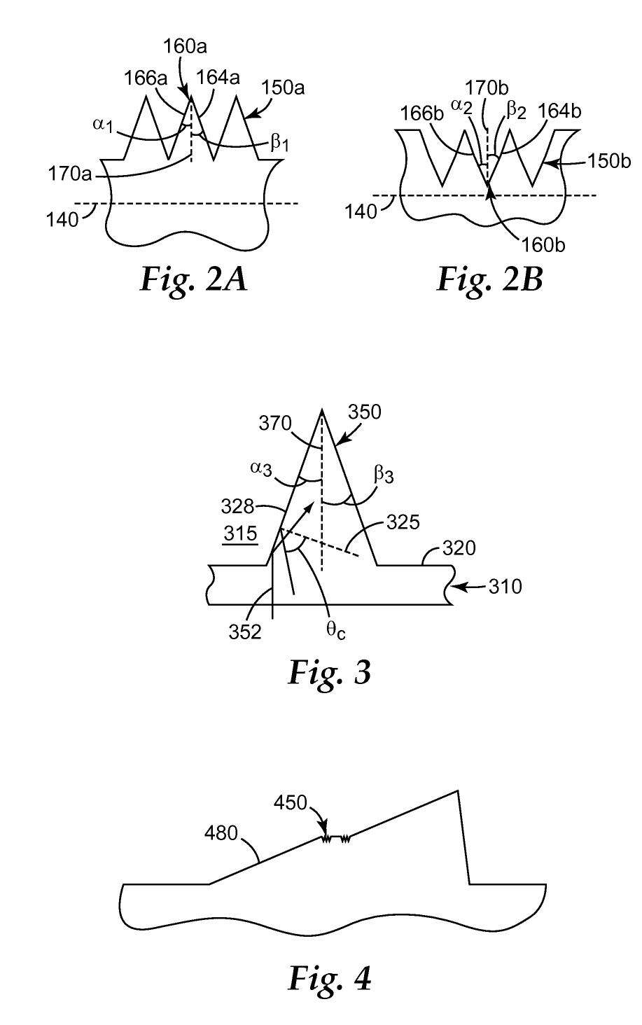

For example, fiducial mark 150 may have a raised profile as shown in FIG. 2A. Referring now to FIG. 2A, fiducial mark 150a is formed by first and second respective frustoconical surfaces (164a, 166a), that together with reference line 170a normal to reference plane 140, define respective first and second half angles (α₁, (β₁) and ellipse-like feature 160a (shown as a ridge). First and second half angles (α₁, (β₁) are both less than or equal to θ_{c} (not shown).

Likewise, fiducial mark 150 may have a recessed profile as shown in FIG. 2B. Referring now to FIG. 2B, recessed fiducial mark 150b is formed by first and second respective frustoconical surfaces (164b, 166b), that together with reference line 170b normal to reference plane 140, define respective first and second half angles (α₂, (β₂) and ellipse-like feature 160b (shown as a groove). First and second half angles (α₂, (β₂) are both less than or equal to θ_{c}.

While FIGS. 2A and 2B respectively depict substantially symmetrical ridges and grooves, this need not be the case as long as both included angles are sufficiently small to give rise to total internal reflection of light traveling within the substrate in a direction perpendicular to the reference plane.

The substrate may be any optically transmissive material with sufficient dimensional stability for its intended use. For example, the substrate may comprise glass or an organic polymer. The organic polymer may be thermoplastic or thermoset. Mixtures of organic polymers may also be used. Examples of suitable organic polymers include polyesters (e.g., polyethylene terephthalate and polyethylene 2,6-naphthalate), cellulosics (e.g., cellulose acetate and cellulose butyrate), acrylics (e.g. polymethyl methacrylate), fluoropolymers, polyolefins (e.g., polyethylene and polypropylene), polyamides, silicones, polyurethanes, polycarbonates, and optically transmissive blends thereof.

Total internal reflection is an optical phenomenon that occurs when a ray of light strikes a medium boundary, passing from higher to lower index of refraction, at an angle larger than a critical angle (θ_{c}) with respect to the normal to the medium boundary. If the refractive index is lower on the other side of the medium boundary, essentially no light passes through and all of the light is reflected.

The critical angle is the angle of incidence above which the total internal reflection occurs. For a given substrate material, the θ_{c} for total internal reflection in air, is a function of the refractive index of air (η₂, equal to 1.00) and the refractive index of the material selected for the substrate (η₁) according to the Equation 1 (below):

θ_{c}=arcsin(η₂/η₁) Equation 1

The foregoing will now be clarified by reference to FIG. 3. Substrate 310 has major surface 320 with fiducial mark 350 disposed thereon, which forms a medium boundary 328 between substrate 310 and air 315. Substrate 310 has critical angle for total internal reflection, θ_{c}, as defined relative to normal (i.e., surface normal) 325. Light 352 impinging on medium boundary 328 at angles less than or equal to 90 degrees minus θ_{c} will be essentially totally internally reflected. Accordingly, first and second half angles (α₃, (β₃) formed with reference line 370 (normal to the reference plane, not shown) should be selected to be less than the quantity 90 degrees minus θ_{c} expressed in degrees.

The refractive index η₁, and hence θ_{c}, can be readily obtained from the literature for many materials, and/or it may be readily determined experimentally by well-known techniques.

In some embodiments, the major surface having the fiducial marking disposed thereon has functional elements. In some embodiments, the fiducial marking may be located on a first major surface, while the functional elements are disposed on a second major surface opposite the first major surface. The fiducial marking(s) may be centrally and/or peripherally disposed on the major surface.

If desired, for example, as shown in FIG. 4, the fiducial marking 450 may be disposed on a functional element 480.

The fiducial marking may have one or more ellipse-like features such as, for example, ridges or grooves (each of which can be formed by the intersection of two frustoconical surfaces. For example, the fiducial marking may comprise at least one, two, three, four, five, or even at least ten ellipse-like features.

In general, the fiducial marking should be of sufficient optical area to be readily detectable by a machine vision system, however, this not a requirement. If the number of substantially ellipse-like features is small, then width (and hence depth or height) of each ellipse-like feature will typically be larger than those cases where the number of ellipse-like features is larger. Typically, adequate contrast to surrounding areas of the substrate can be achieved according to the present disclosure using fiducial markings with an area of less than five square millimeters (mm²), less than two mm², or even less.

The substantially ellipse-like features which may be close-packed and/or separated by land area.

The substantially ellipse-like features are typically ellipse-like (including circular) and free of surface defects, however it will be recognized that minor deviations in design or manufacturing flaws may be tolerated without overly degrading the contrast to adjacent portions of the substrate.

The substrate may optionally further comprise one or more functional elements. Examples of functional elements include prisms, lenses, channels, electronic components, pixel arrays and precursors thereof. In some embodiments (e.g., see FIG. 1), the functional elements comprises lens elements of a Fresnel lens.

Fiducials according to the present disclosure may be made by, for example, using conventional processes such as compression molding, injection molding, or continuous casting using precision replication processes. The present fiducials are particularly advantageous in instances (e.g., a Fresnel lens) where such processes would ordinary be used in manufacture of the substrate absent the fiducial marking.

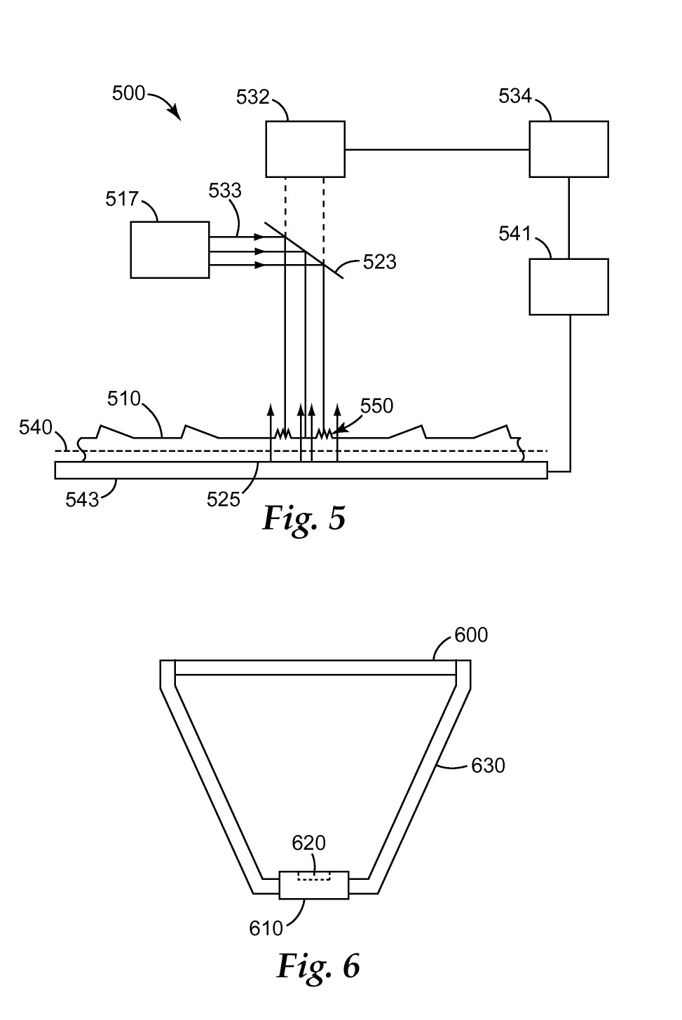

Fiducials according to the present disclosure are useful in combination with a machine vision system for precise position determination, and typically with appropriate precision alignment equipment, although the latter is not a requirement. FIG. 5 depicts an exemplary of machine vision detection/manipulation system 500. In the configuration shown, light 533 from light source 517 is reflected off partially reflective mirror 523 and onto substrate 510 at an angle substantially normal to reference plane 540. At least some of light 533 impinging on substrate 510 passes through substrate 510 and is reflected at the opposite substrate surface 525 back toward camera 532. In the configuration shown, light 533 impinging on fiducial marking 550 is substantially prevented from returning to the camera at an angle normal to reference plane 540.

As shown, camera 532 is substantially coaxially aligned with light 533, although other configurations may be used. For example, the light source may alternatively be a ring light mounted in line with the camera. In some embodiments, the light source and the camera may be disposed facing the same side of the substrate (reflection mode) as shown in FIG. 5. In other embodiments, the light source and the camera may be disposed facing opposite sides of the substrate (transmission mode).

Depending on the precise configuration used, the fiducial marking may appear, for example, as either a dark ellipse-like feature (e.g., a black ellipse-like ring) or a bright ellipse-like feature (e.g., a reflective ellipse-like ring). For example, raised fiducials facing the light and camera typically give rise to dark ellipse-like features, while raised fiducials disposed on the substrate facing away from the light and camera typically give rise to bright reflective ellipse-like features.

Camera 532 is in communication with computer 534 that has image recognition software implemented thereon. Various image recognition software products are commercially available. One useful image recognition software package is available as SENTRY 9000, Version 8, Build 15, from AccuSentry, Inc. of Marietta, Ga.

Through the image recognition software, the computer determines the precise location (typically to within about 10 micrometers or less) of the fiducial marking and hence the substrate. Typically, computer 534 is in communication with a controller 541 for a positioning device 543 (e.g., a translatable stage or web handling equipment)) capable of precisely translating the substrate to a desired position/orientation.

Fiducial markings according to the present disclosure are advantageously used in combination with transparent substrates in articles such as, for example, electronic display screens (e.g., plasma or LCD television screens) and solar energy devices wherein, as shown in FIG. 6, a Fresnel lens 600 is precisely positioned over a module assembly 610 containing a photovoltaic cell 620 by frame 630. Similar advantages may be realized if module assembly 610 is replaced by a thermal solar collector.

Objects and advantages of this disclosure are further illustrated by the following non-limiting examples, but the particular materials and amounts thereof recited in these examples, as well as other conditions and details, should not be construed to unduly limit this disclosure.

### EXAMPLES

### Comparative Example A

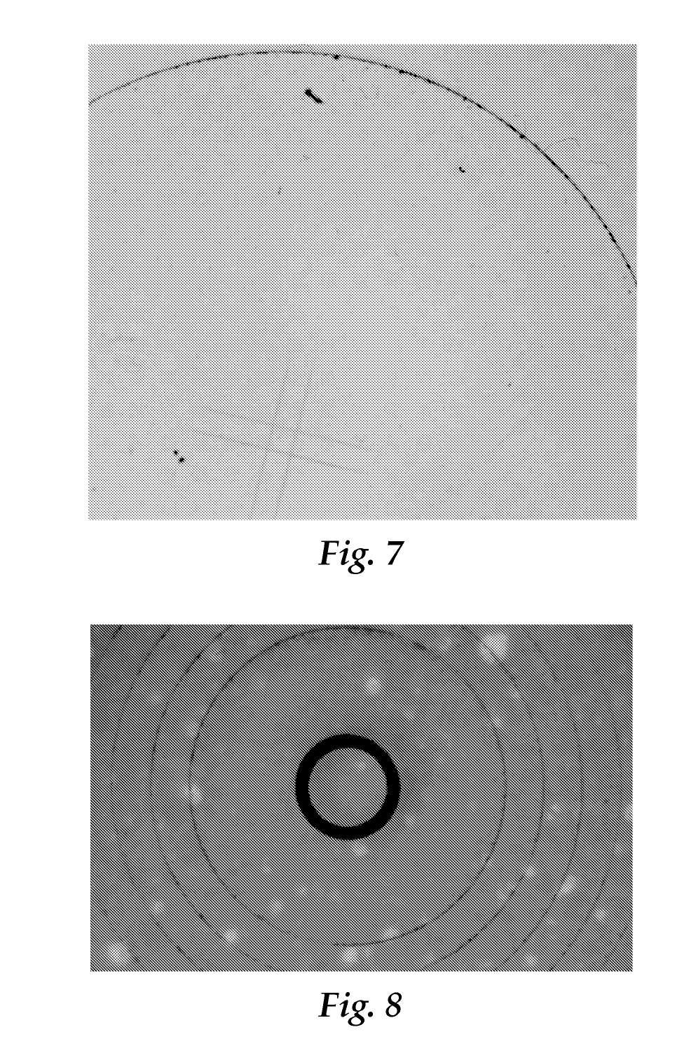

A molded polymethyl methacrylate (PMMA) Fresnel lens of diameter 12.75 inches (32.4 cm) and 3.5 mm thickness was produced with a cross-hatched fiducial marking that was created during machining of the Fresnel mold master. The fiducial marking as shown in FIG. 7, viewed under normal incidence illumination conditions, was about 2 mm by 2 mm by 10 micrometers in depth.

The Fresnel lens was viewed with a machine vision system available under the trade designation SENTRY 9000 from Accusentry, Inc. of Marietta, Ga., viewing at an angle normal to the plane of the Fresnel lens and substantially along the path of the light used to illuminate the lens. The Fresnel lens was arranged such that the fiducial was facing toward the camera). The machine vision system did not successfully determine the center of the fiducial marking. Additional commercially available machine vision systems were also tried with substantially equivalent results.

### Example 1

A molded PMMA Fresnel lens of diameter of approximately 50 mm and 3.5 mm thickness was produced with a circular fiducial marking that was created during machining of Fresnel mold master. Precisely machining the fiducial into the lens mold at the same time as the machining of the Fresnel lens ensured that the fiducial was precisely located in the center of each Fresnel lens. Attempting to add a circular fiducial after a lens is cut generally provides a lower level of accuracy.

The circular fiducial marking was about 2 millimeters in its outer diameter and consisted of five consecutive circular grooves having half angles of 45 degrees (i.e., the total included angle was 90 degrees) and a pitch of 50 micrometers.

FIG. 8 is a digital photograph of the Fresnel lens taken using the camera of a machine vision system available under the trade designation SENTRY 9000 from Accusentry, Inc. of Marietta, Ga., viewing at an angle normal to the plane of the Fresnel lens and substantially along the path of the light used to illuminate the lens. The Fresnel lens was arranged such that the circular fiducial was facing toward the camera (i.e., on the closest face of the lens with respect to the camera and incident light).

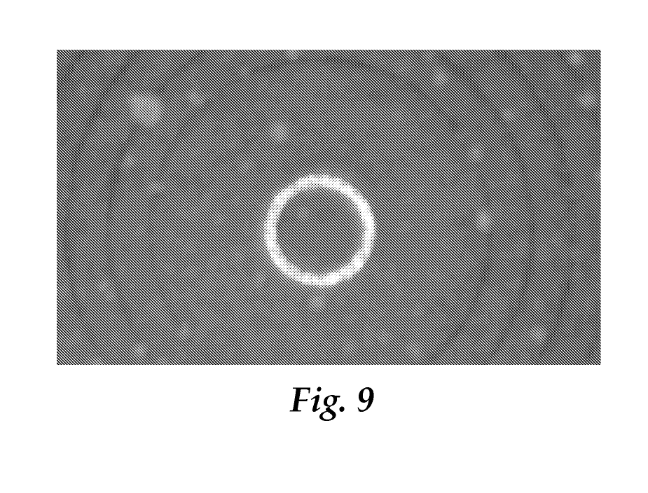

FIG. 9 is a digital photograph taken using the camera of the machine vision system used to generate FIG. 8, viewing at the same angle as in FIG. 8, but with the circular fiducial facing away from the camera (i.e., the Fresnel lens was flipped over relative to its orientation in FIG. 8).

In both configurations shown in FIG. 8 and FIG. 9 the machine vision system was able to detect the fiducial marking and detect the position of its center within a tolerance of 50 micrometers.

All patents and publications referred to herein are hereby incorporated by reference in their entirety. All examples given herein are to be considered non-limiting unless otherwise indicated. Various modifications and alterations of this disclosure may be made by those skilled in the art without departing from the scope and spirit of this disclosure, and it should be understood that this disclosure is not to be unduly limited to the illustrative embodiments set forth herein.

1. An article comprising a substrate having a major surface, wherein the substrate is optically transmissive and has a critical angle for total internal reflection, wherein the substrate has a length and a width defining a reference plane, wherein the substrate comprises an integral fiducial mark disposed on the major surface, wherein the fiducial mark comprises at least one substantially ellipse-like feature formed by first and second frustoconical surfaces that together with a reference line that is normal to the reference plane define respective first and second half angles, and wherein the first and second half angles are less than or equal to 90 degrees minus the critical angle for total internal reflection expressed in degrees.

2. The method of claim 1, wherein the substrate further comprises a plurality of functional elements.

3. The method of claim 1, wherein the at least one substantially ellipse-like feature comprises a ridge extending outwardly from the major surface

4. The method of claim 1, wherein the at least one substantially ellipse-like feature comprises a groove extending inwardly from the major surface

5. The method of claim 2, wherein the plurality of functional elements comprises at least one of optical or electronic elements.

6. The method of claim 2, wherein the plurality of functional elements comprises a Fresnel lens.

7. The method of claim 6, further comprising a photovoltaic cell, wherein the Fresnel lens is optically aligned with respect to the photovoltaic cell.

8. The method of claim 1, wherein the integral fiducial mark is centrally disposed with respect to the major surface.

9. The method of claim 1, wherein the integral fiducial mark has an area of less than or equal to 2 square millimeters.

10. The method of claim 1, wherein the at least one substantially ellipse-like feature is circular.

11. The method of claim 2, wherein the integral fiducial mark is formed on at least one of the plurality of functional elements.

12. The method of claim 1, wherein the substrate comprises an organic polymer.

13. A method comprising:
providing a substrate having a first major surface, wherein the substrate is optically transmissive and has a critical angle for total internal reflection, wherein the substrate has a length and a width defining a reference plane, wherein the substrate comprises an integral fiducial mark disposed on the first major surface, wherein the fiducial mark comprises at least one substantially ellipse-like feature formed by first and second frustoconical surfaces that together with a reference line that is normal to the reference plane define respective first and second half angles, and wherein the first and second half angles are less than or equal to 90 degrees minus the critical angle for total internal reflection expressed in degrees; and
precisely detecting a position of the integral fiducial mark using a machine vision system, wherein the machine vision system comprises a camera aligned to receive light normal to the reference plane, and wherein the camera is in communication with a computer having image analysis software implemented thereon.

14. The method of claim 13, further comprising precisely aligning the substrate.

15. The method of claim 13, wherein the substrate further comprises a plurality of functional elements.

16. The method of claim 13, wherein the at least one substantially ellipse-like feature comprises a ridge extending outwardly from the first major surface

17. The method of claim 13, wherein the at least one substantially ellipse-like feature comprises a groove extending inwardly from the first major surface

18. The method of claim 13, wherein the machine vision system further comprises a light source that emits light substantially coaxially aligned with the camera.

19. The method of claim 18, wherein the substrate further comprises a second major surface opposite the first major surface, and wherein the camera is disposed facing the second major surface.

20. The method of claim 18, wherein the light source and the camera are disposed facing the same side of the substrate

21. The method of claim 15, wherein the plurality of functional elements comprises at least one of optical or electronic elements.

22. The method of claim 15, wherein the plurality of functional elements comprises a Fresnel lens.

23. The method of claim 22, further comprising a photovoltaic cell, wherein the Fresnel lens is optically aligned with respect to the photovoltaic cell.

24. The method of claim 13, wherein the integral fiducial mark is centrally disposed with respect to the first major surface.

25. The method of claim 13, wherein the integral fiducial mark has an area of less than or equal to 2 square millimeters.

26. The method of claim 13, wherein the at least one substantially ellipse-like feature is circular.

27. The method of claim 13, wherein the integral fiducial mark is formed on at least one of the plurality of functional elements.

28. The method of claim 13, wherein the substrate comprises an organic polymer.
